(19) United States
(12) Patent Application Publication
(10) Pub. No.: US 2025/0157709 A1
(43) Pub. Date: May 15, 2025

(54) INDUCTOR AND POWER SUPPLY

(71) Applicants: HUIZHOU POCO NEW INDUCTOR TECHNOLOGY CO., LTD., Huizhou City (CN); HEYUAN POCO NEW MATERIAL CO., LTD., Heyuan City (CN)

(72) Inventors: TAO LUO, Shenzhen City (CN); YUNFAN ZHANG, Shenzhen City (CN); XIONGZHI GUO, Shenzhen City (CN); ZHIDA LIU, Shenzhen City (CN)

(21) Appl. No.: 18/940,795

(22) Filed: Nov. 7, 2024

(30) Foreign Application Priority Data
Nov. 14, 2023 (CN) 202311512818.7

(51) Int. Cl. H01F 5/04; H01F 27/29; H01F 37/00

(52) U.S. Cl. CPC H01F 5/04; H01F 27/292; H01F 37/00

(57) ABSTRACT

An inductor provided in the present invention includes multiple windings in the magnetic core. The multiple windings comprise a first, second, third and fourth windings. Second and third windings have been connected in series to form an integrated series winding inside the magnetic core with two leads exposed on the surface of the magnetic core for electrical connection with the power supply circuit. The first winding is magnetically coupled to the second winding, and the fourth winding is magnetically coupled to the third winding. A pair of leads at both ends of the first winding and a pair of leads at both ends of the fourth winding are exposed on the surface of the magnetic core for electrical connection with the power supply circuit. The inductor is welded on the circuit board, which saves the number of weld points, makes circuit connection more reliable and reduces DCR.

### CROSS REFERENCE TO RELATED APPLICATIONS

The present invention is 35 U.S.C. § 119 benefit of earlier filing dates; rights of priority of Chinese Applications No. 202311512818.7 filed on Nov. 14, 2023, the disclosure of which is incorporated by reference herein.

### BACKGROUND OF THE INVENTION

### Field of the Invention

The present invention relates to the field of electronic components, and more particularly, to an inductor and a power supply.

### Description of Related Art

In recent years, with the development of technologies such as data centers, artificial intelligence, Central Processing Units (CPUs), Graphics Processing Units (GPUs) and various Integrated Chips (ICs) are running faster and faster, higher and higher operating currents is required, such as an operating current at the ampere level, ranging from tens to hundreds of amps; and requiring a Voltage Regulator Module (VRM) with a higher power density, efficiency, and dynamic performance. A design of the VRM is encountering high challenges. The output inductor often takes up the largest space in the VRM, and at the same time, the selection of inductance also directly affects the efficiency and dynamic performance of the VRM.

The Trans-inductor Voltage Regulator (TLVR) is a power supply structure for a Voltage Regulator (VR) newly developed in recent years. Compared with the traditional DC-DC Buck or DC (Direct Current) structures, the main difference of the TLVR is that the traditional single-turn winding inductor is replaced with a double-turn winding transformer like TLVR inductor. The ordinary inductor has each single-turn winding with two ends, while the TLVR inductor has two sets of mutually coupled windings with 4 ends in total, such difference can reduce the space of the inductor occupied on the PCB.

In order to provide the required working voltage for the Central Processing Unit (CPU), the Graphics Processing Unit (GPU) or various Integrated Chips (ICs), the VRM needs to be configured with multiple TLVR inductors. Multiple TLVR inductors will increase the size of the TLVR, occupy a larger area/space on the circuit board and more circuit wiring needs to be laid out on the circuit board, which causes DCR (Direct Current Resistance, DCR) to increase.

### SUMMARY OF THE INVENTION

A main object of the present invention is to provide an inductor, which needs less space, fewer weld points and fewer circuit wiring when welded to a power supply circuit on a circuit board, and thus having a more reliable electrical connection and reducing the DCR.

In a first aspect, an inductor provided by the present invention, comprises a magnetic core and windings provided in the magnetic core with leads exposed on a surface of the magnetic core for electrical connection with a power supply circuit on a circuit board; the windings comprises a first winding, a second winding, a third winding and a fourth winding; the second winding and the third winding have been internally connected in series to form an integrated series winding inside the magnetic core; two leads of the integrated series winding extend to be exposed on the surface of the magnetic core for electrical connection with the power supply circuit; the first winding is magnetically coupled to the second winding, the fourth winding is magnetically coupled to the third winding; a pair of leads at both ends of the first winding and a pair of leads at both ends of the fourth winding extend to be exposed on the surface of the magnetic core for electrical connection with the power supply circuit.

In some embodiments, the first winding, the second winding, the third winding and the fourth winding are configured such that there is a predetermined projection overlap between the first winding and the second winding, and there is a predetermined projection overlap between the third winding and the fourth winding.

In some embodiments, the first winding is located outside, above or below the second winding; the fourth winding is located outside, above or below the third winding.

In some embodiments, the second winding and the third winding are primary windings for electrical connection with ground points of the power supply circuit; the first winding and the fourth winding are secondary windings for electrical connection with different power stages of the power supply circuit.

In some embodiments, the second winding and the third winding have been internally connected in series to form the integrated series winding inside the magnetic core in any of following ways:
a first way that: merging two adjacent leads of the second winding and the third winding into an intermediate conductor for connecting between the second winding and the third winding to form the integrated series winding with the two leads extending to be exposed on the surface of the magnetic core;
a second way that: connecting two adjacent leads of the second winding and the third winding through an intermediate conductor whereby the second winding and the third winding are connected in series to form the integrated series winding with the two leads extending to be exposed on the surface of the magnetic core;
a third way that: two adjacent leads of the second winding and the third winding are not set, and the second winding and the third winding have their main body directly connected in series to form the integrated series winding;
a fourth way that: two adjacent leads of the second winding and the third winding are not set, and the second winding and the third winding have their main body connected in series through an intermediate conductor to form the integrated series winding.

In some embodiments, the first winding and the fourth winding are U-shaped; the second winding and the third winding are U-shaped or Z-shaped; the integrated series winding comprises a body part and the two leads; the body part of the integrated series winding forms a single or multiple U-shapes or Z-shapes or a straight line. The two leads of the integrated series winding are bent relative to the body part of the integrated series winding, then extend to be exposed on the surface of the magnetic core; and the two leads are arranged at first and last ends of the integrated series winding.

In some embodiments, each of the first winding, the second winding, the third winding, and the fourth winding comprises a main body and one or two leads; the one or two leads are provided at one or both ends of the main body, and are bent relative to the main body and extend to be exposed on the surface of the magnetic core; the one or two leads of each winding have the same cross-sectional shape as the main body of the corresponding winding; or, a width of one or both of two adjacent leads is reduced to increase a distance between the two adjacent leads exposed on the surface of the magnetic core to prevent short circuits when the leads are welded to the power supply circuit on the circuit board. The first winding, the second winding, the third winding and the fourth winding that are exposed on the surface of the magnetic core are bent again and extend along the surface of the magnetic core to increase a distance between the adjacent leads exposed on the surface of the magnetic core and to expand areas of the leads exposed on the surface of the magnetic core to facilitate welding the leads to the circuit board.

In some embodiments, the second winding, the third winding and the fourth winding are arranged side by side along a first direction, the first winding is arranged close to the second winding, and the third winding is arranged close to the fourth winding. The first winding and the fourth winding are arranged side by side along a first direction, the second winding and the third winding are arranged along a second direction and correspond to the first winding and the first winding respectively; where the first direction and the second direction are perpendicular to each other. The first winding and the second winding are arranged in parallel, the fourth winding and the third winding are arranged in parallel; the first winding and the fourth winding are the same winding; the second winding and the third winding are the same winding; and the leads of the first winding, the second winding, the third winding and the fourth winding are exposed on the same side surface of the magnetic core.

In some embodiments, the windings comprises one or more first windings, one or more second windings, one or more third windings, and one or more fourth windings, which are set in the magnetic core according to a principle that: one second winding and one third winding are connected in series to form the integrated series winding, one more second winding and/or one more third winding is connected into the integrated series winding, then one more first winding and/or one more fourth winding is set correspondingly, whereby the windings are expanded to form a multi-magnetic coupling inductor.

In a second aspect, a power supply provided by the present invention, comprises a circuit board and one or more inductors of any of the above embodiments, the circuit board is provided with a power supply circuit; the inductor is electrically connected to the power supply circuit.

Further, corresponding to the integrated series winding inside the magnetic core, the power supply circuit provides two ground points for being respectively welded and electrically connected with the two leads at both ends of the integrated series winding; corresponding to each of the first winding and the fourth winding, the power supply circuit provides a pairs of weld points for being respectively welded and electrically connected to the pairs of leads of each of the first winding and the fourth winding.

In some embodiments, the power supply is used as the power supply for a server, or a data center, or a power processor of a storage system, or a memory; an operating current of the power supply reaches an ampere level; and the operating current of the power supply ranges from tens to hundreds of amperes.

The advantages of the present invention are:

In the inductor of the present invention, the second winding and the third winding have been connected in series inside the magnetic core, and other two far apart leads as the two common ends exposed on the surface of the magnetic core. Therefore, the number of weld points for welding the inductor to the power supply circuit is reduced, making the circuit connection more reliable and DCR (Direct Current Resistance) smaller. Further, the second winding and the third winding have been connected in series inside the magnetic core, there is no need to lay out corresponding series circuit wiring on the circuit board, there are fewer lines on the circuit board, which reduces a wiring space occupied on the circuit board, and there is more space used to lay out other components such as chips (such as CPUs and GPUs).

### BRIEF DESCRIPTION OF DRAWINGS

FIG. 1 is a front view of an inductor in accordance with an embodiment of the present invention;

FIG. 2 is a top view of the inductor in accordance with a first embodiment of the present invention;

FIG. 3 is a perspective view of an inductor in accordance with the first embodiment of the present invention;

FIG. 4 is a top view of the inductor in accordance with a second embodiment of the present invention;

FIG. 5 is a perspective view of the inductor in accordance with the second embodiment of the present invention;

FIG. 6 is a top view of the inductor in accordance with a third embodiment of the present invention;

FIG. 7 is a perspective view of the inductor in accordance with the third embodiment of the present invention;

FIG. 8 illustrates a diagram of weld points on the circuit board for welding a TLVR inductor, where figures (a) and (b) are different examples of circuit wiring respectively;

FIG. 9 illustrates a diagram of weld points on a circuit board for welding a comparative inductor, where figures (a) and (b) are different examples of circuit wiring respectively;

FIGS. 10-11 are different perspective views of the inductor in accordance with a fourth embodiment of the present invention;

FIG. 12 is a perspective view of the inductor in accordance with a fifth embodiment of the present invention;

FIG. 13 is a perspective view of the inductor in accordance with a sixth embodiment of the present invention; and

FIG. 14 is a perspective view of the inductor in accordance with a seventh embodiment of the present invention.

### DETAILED DESCRIPTION OF THE INVENTION

Certain exemplary embodiments will now be described to provide an overall understanding of the principles of the structure, function, manufacture, and use of the devices and methods disclosed herein. One or more examples of these embodiments are illustrated in the accompanying drawings. Those of ordinary skill in the art will understand that the devices and methods specifically described herein and illustrated in the accompanying drawings are non-limiting exemplary embodiments. The features illustrated or described in connection with one exemplary embodiment may be combined with the features of other embodiments. Such modifications and variations are intended to be included within the scope of the present invention.

Although the terms “first”, “second”, etc. may be used herein to describe various elements, components, regions, layers and/or sections, these elements, components, regions, layers and/or sections shall not be referred to as restricted by these terms. These terms are only used to distinguish one element, component, region, layer or section from another region, layer or section. Terms such as “first,” “second,” and other numerical terms when used herein do not imply a sequence or order unless clearly indicated by the context. Thus, an element, component, region, layer or section discussed below could be termed a second element, component, region, layer or section without departing from the teachings of the example embodiments.

It will be further appreciated that, for convenience and clarity, spatial terms such as “vertical,” “horizontal,” “up”, “down”, “internal”, “external”, “inside”, “outside”, “below”, “beneath”, “under”, “on”, “top”, “bottom”, “front”, “rear”, “left”, “right”, “horizontal”, “vertical” and etc., may be used herein with respect to the drawings. However, the device is used in many orientations and positions, and these terms are not intended to be limiting and/or absolute. For example, if the device in the figures is turned over, elements described as “below” other elements or features would then be oriented “above” the other elements or features. Thus, the example term “below” may include an orientation of above and below. The device may be otherwise oriented (rotated 90 degrees or at other orientations) and the orientation herein should be interpreted accordingly. It may be noted that some figures are shown with partial transparency for the purpose of explanation, illustration and demonstration purposes only, and is not intended to indicate that an element itself would be transparent in its final manufactured form.

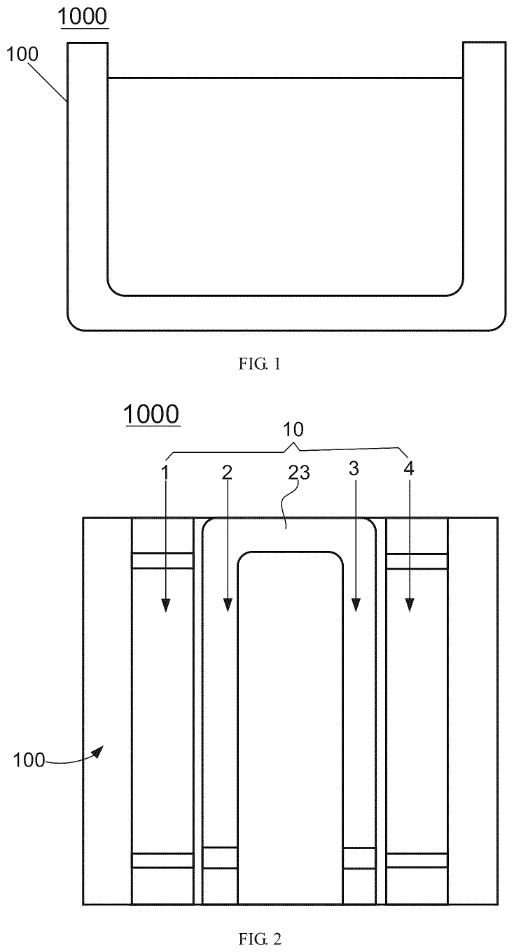

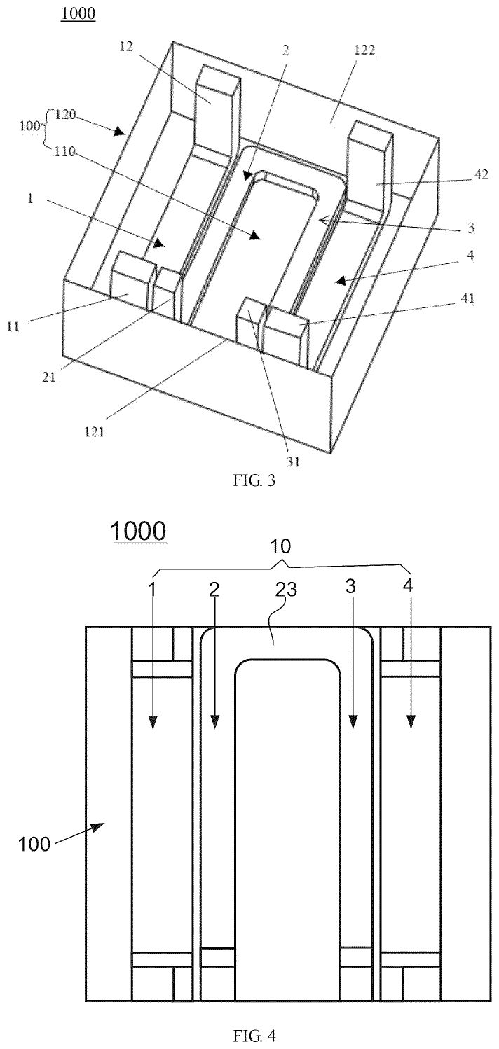

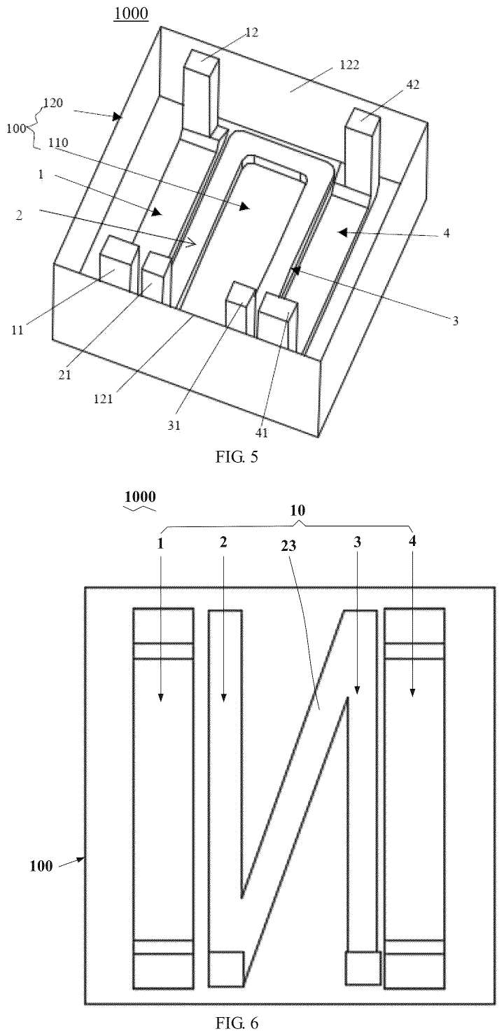

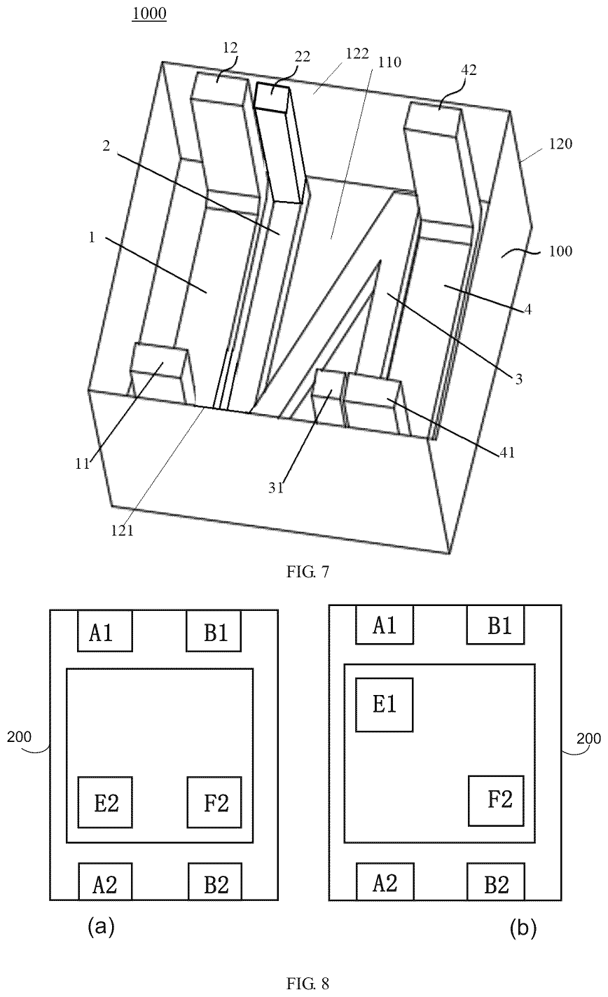

Referring to FIGS. 1-14, an inductor 1000 provided in the present invention, can be used as a TLVR inductor; and it is mainly used in power supplies with high powers and high operating currents, such as a power supply for a chip at an operating current of an ampere level high to tens to hundreds of amperes. The power supply includes one or more inductors 1000 and a circuit board 200. The circuit board 200 is provided with a power supply circuit. The inductors 1000 are connected to the power supply circuit. The windings and the magnetic core form the inductor 1000 used for energy storage.

The inductor 1000 of the present invention includes a magnetic core 100 and multiple windings 10 arranged inside the magnetic core 100. The leads of windings are exposed on the surface of the magnetic core 100 and are connected to the power supply circuit on the circuit board 200. The multiple windings 10 includes a first winding 1, a second winding 2, a third winding 3 and a fourth winding 4. Four windings 1, 2, 3 and 4 set in the magnetic core 100 forms the two-phase coupled inductor 1000. Each winding includes a main body and one or two leads provided at the ends of the main body. Each of the first winding 1 and the fourth winding 4 has two leads at both ends of a main body thereof. Therefore, each of the first winding 1 and the fourth winding 4 has a pair of leads exposed on the surface of the magnetic core and electrically connected to a power supply circuit on the circuit board 200. The second winding 2 and the third winding 3 are connected in series inside the magnetic core 100 to form an integrated series winding by means of the two adjacent leads being connected or merged, or by means of the main bodies being connected. In this embodiment, one end of the main body of each of the second winding 2 and the third winding 3 is connected to each other, and the other end is provided with a lead exposed on the surface of the magnetic core 100 for electrical connection with the circuit board 200. In an energized state, the first winding 1 and the second winding 2 are magnetically coupled to obtain a first magnetic coupling, and the third winding 3 and the fourth winding 4 are magnetically coupled to obtain a second magnetic coupling. The first winding 1 and the fourth winding 4 are used as secondary windings to be connected to different power stages of the power supply circuit on the circuit board 200, and the second winding 2 and the third winding 3 are used as primary windings to be connected to ground points of the power supply circuit on the circuit board 200.

Where the second winding 2 and the third winding 3 are internally connected to form an integrated series winding inside the magnetic core 10, and the internal connection way can be any one of:
a first way that: the second winding 2 and the third winding 3 have their adjacent leads merged to form an intermediate conductor 23 as a common lead so that the two windings 2 and 3 are connected in series to form the integrated series winding, and each of the two windings has one unconnected lead respectively;
a second way: the second winding 2 and the third winding 3 have their adjacent leads connected through an intermediate conductor 23 so that the two windings are connected in series through the intermediate conductor 23 to form the integrated series winding;
a third way: the second winding 2 and the third winding 3 have their main body directly connected in series with each other to form the integrated series winding, wherein the two adjacent leads of the windings 2 and 3 are not provided, each of the two windings has one free lead;
a fourth way: the second winding 2 and the third winding 3 have their main body connected in series through an intermediate conductor 23 to form the integrated series winding, wherein the two adjacent leads of the windings 2 and 3 are merged into the intermediate conductor 23 as the common lead of the two windings 2 and 3.

In some embodiments, the first way is similar to the fourth way, referring to the embodiments shown in FIGS. 2-7 and 10-13, the adjacent leads of the second winding 2 and the third winding 3 can be machined into an intermediate conductor 23 and connected between the adjacent sides of the two main bodies and in the same plane as the main bodies of the windings 2 and 3. The second winding 2 and the third winding 3 have one side are directly connected to each other through the inner conductor 23. Each of the main bodies of the second winding 2 and the third winding 3 has the other end with a lead bent from the main body and extended to the surface of the magnetic core for connection with the circuit board 200.

In some embodiments, as the second way, referring to FIG. 14, the second winding 2 and the third winding 3 have their adjacent leads connected together through the inner conductor 23.

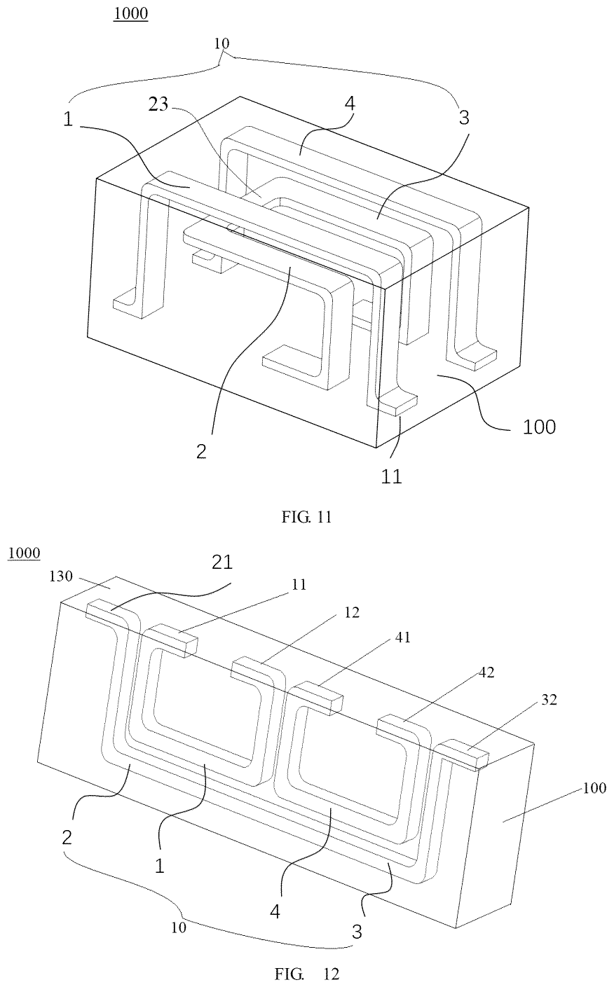

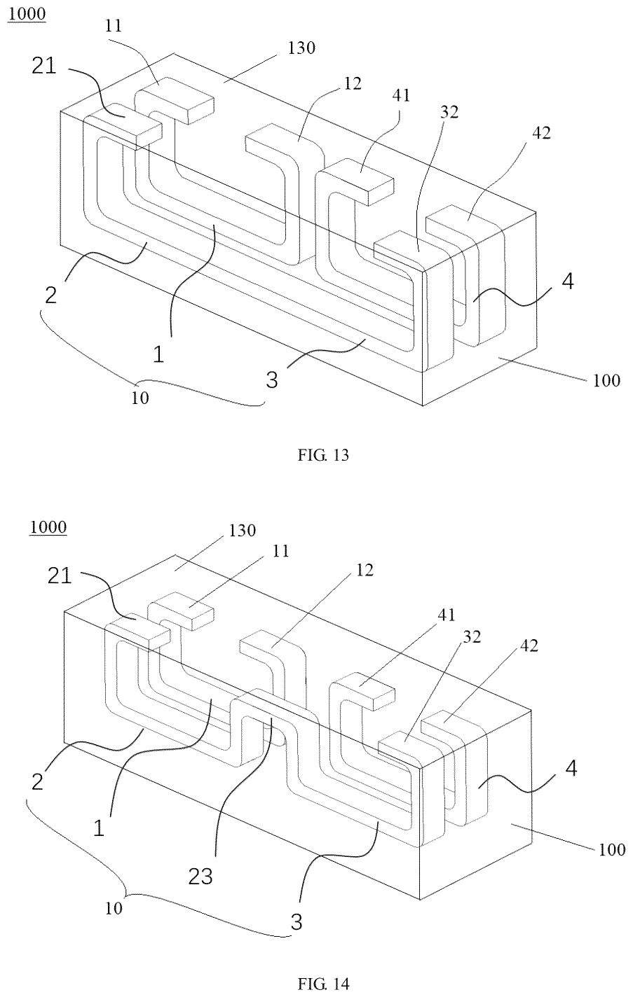

In some embodiments, as the third way, referring to FIGS. 12-13, the second winding 2 and the third winding 3 have main bodies connected directly, and their adjacent leads are not provided.

The second winding 2 and the third winding 3 can be U or Z-shaped. If the U-shaped second winding 2 and third winding 3 are not connected internally, as independent U-shaped windings, each includes a straight (or nearly straight) main body and two leads (as arms of the U-shape) bent from both sides of the main body in the same direction; when the second winding 2 and the third winding 3 are internally connected, two adjacent leads thereof are merged into an intermediate conductor 23 through mechanical processing to connect their two main bodies; or two adjacent leads are not set while an intermediate conductor 23 are provided to connect their main bodies, and two far apart leads of the second winding 2 and the third winding 3 are exposed on the surface of the magnetic core 100 for connection to the circuit board 200. If the Z-shaped second winding 2 and third winding 3 are not connected internally, as independent Z-shaped windings, each includes a straight (or nearly straight) main body and two leads bent from both sides of the main body in opposite directions; when the second winding 2 and the third winding 3 are internally connected, two adjacent leads thereof are merged into an intermediate conductor 23 through mechanical processing to connect their main bodies; or two adjacent leads are not provided while an intermediate conductor 23 are provided to connect their main bodies, and two far apart leads of the second winding 2 and the third winding 3 are exposed on the surface of the magnetic core 100 for connection to the circuit board 200.

In some embodiments, the second winding 2 and the third winding 3 are placed side by side in parallel and internally connected to form an integrated series winding in the magnetic core 100, a body part of the integrated series winding is U-shaped or Z-shaped (as shown in FIGS. 2-7, and 10-11). Two leads are provided (for example, bent vertically) at both ends of the U-shaped or Z-shaped body part of the integrated series winding, are exposed on the surface of the magnetic core, and are connected to the ground points on the circuit board 200.

In some embodiments, the second winding 2 and the third winding 3 are connected in a linear manner, referring to FIGS. 12-13, the second winding 2 and the third winding 3 are internally connected to form an integrated series winding. The body part of the integrated series winding is straight in line, two leads are provided (for example, bent vertically) at opposite ends of the straight body part of the integrated series winding, extend to be exposed on the surface of the magnetic core, and are connected to the ground points on the circuit board 200. At this time, the second winding 2 and the third winding 3 are internally connected to form a U-shaped series winding (including the straight body part and two bent leads at both sides).

In other embodiments, referring to FIG. 14, according to the above-mentioned second way, the second winding 2 and the third winding 3 are linearly or straightly connected end to end, the ends of two adjacent leads (bent perpendicularly to the main body of the winding 2 or 3) are connected end to end through the intermediate conductors 23 to form a U-shaped or Z-shaped connection part, connecting the straight main bodies of the front and rear second winding 2 and the third winding 3 together.

The intermediate conductor 23 connecting the second winding 2 and the third winding 3 can be in various shapes. The shapes, sizes and arrangements of the first winding 1, the second winding 2, the third winding 3 and the fourth winding 4 of the multiple windings 10 are adjustable according to the application scenario. There is a preset projection overlap between the first winding 1 and the second winding 2, and there is a preset projection overlap between the third winding 3 and the fourth winding 4. The four windings 1-4 set in the magnetic core 100, wherein the first and second windings 1, 2 are coupled to each other, the third and fourth windings 3, 4 are coupled to each other, therefore forms two-phase coupled inductor 1000. The first winding 1, the second winding 2, the third winding 3 and the fourth winding 4 are arranged side by side along a first direction, the first winding is arranged close to the second winding; the third winding is arranged close to the fourth winding. Or, the first winding and the fourth winding are arranged along a first direction side by side, and the second winding and the third winding are arranged corresponding to the first winding and the fourth winding respectively along a second direction; where the first direction and the second direction are perpendicular to each other. Where the first direction and the second direction may be the x-axis, y-axis or z-axis or parallel directions thereof in the xyz coordinate system. For example, the first winding 1 and the fourth winding 4 are symmetrically arranged on both sides, above or below the integrated series winding, the first winding 1 is close to the second winding 2, and the fourth winding 4 is close to the third winding 3. The second winding 2 and the third winding 3 can be arranged side by side in parallel, or they can be linearly connected end to end; the first winding 1 is arranged in parallel on one side, above or below the second winding 2 and the two ends of the two windings 1 and 2 are aligned respectively, and the fourth winding 4 is arranged in parallel on one side, above or below the third winding 3 and the two ends of the two windings 4 and 3 are aligned respectively.

The inductor 1000 can be two phases or multiphases, the multiple windings 10 provided in the magnetic core 100 includes a first winding 1, a second winding 2, a third winding 3, and a fourth winding 4, where the second winding 2 and the third winding 3 are connected in series to form an integrated series winding inside the magnetic core. The multiple windings 10 are set in magnetic core according to a principle that: one more primary winding (second winding 2 or third winding 3) is added in the magnetic core, one more corresponding coupled secondary winding (first winding 1 or fourth winding 4) is added corresponding to the added primary winding, thereby the integrated inductor with multi-magnetic couplings or multiphase can be obtained. The integrated inductor with multi-magnetic couplings may have odd number of magnetic couplings or even number of magnetic couplings. The inductor 1000 has one or more first windings 1, one or more second windings 2, one or more third windings 3, and one or more fourth windings 4 installed in the magnetic core 100, where one second winding 2 and one third winding 3 have been electrically connected in series inside the magnetic core to form an integrated series winding, one first winding 1 is magnetically coupled to the second winding 2 and one fourth winding 4 is magnetically coupled to the third winding 3, and the integrated inductor with multi-magnetic couplings has at least one integrated series winding formed inside the magnetic core. Multiple second windings 2 and third windings 3 are primary windings, wherein one second winding 2 and one third winding 3 have been electrically connected in series inside the magnetic core 100, thereby less series circuits and less ground points provided are on the circuit board for electrical connection with these two windings 2 and 3. Other primary windings 2 and 3 are electrically connected inside the magnetic core 100, too; or, other primary windings 2 and 3 are not electrically connected inside the magnetic core 100, while more series circuits and more ground points are provided on the circuit board for electrically connection with these primary windings 2 and 3. The magnetic core 100 and the windings 10 are formed into an integrated structure by means of magnetic powder-winding molding, or by multiple magnetic cores each with windings therein are assembled to form the inductor. One or more inductors 1000 are connected to the power supply circuit of the circuit board 200.

In some embodiments, the inductor of the present invention can be produced by a method of magnetic powder-winding molding. The multiple windings 10 is arranged inside the magnetic core 100, and the leads are exposed on the surface of the magnetic core. The method of magnetic powder-winding molding includes a compression molding step and an annealing step. At the compression molding step, place the one or more first windings 1, the one or more second windings 2, the one or more third windings 3, and the one or more fourth windings 4 in a mold cavity at predetermined positions, fill the mold cavity with magnetic powder, press at molding pressure of 12-24 T/cm², then obtain a raw inductor with the multiple windings 10 buried inside the magnetic core 100 and with the leads exposed on the surface of the magnetic core 100. At the annealing step, heat and anneal the raw inductor in a furnace under 400-850° C. to release residual stress in the magnetic core generated at the compression molding step, and obtain the inductor of high dynamic response.

The magnetic powder may be one or a combination of several powders selected from iron powder, iron-silicon alloy powder, iron-silicon-aluminum alloy powder, iron-nickel alloy powder, etc. or, may be amorphous iron-based powder. In some embodiments, the magnetic powder is insulating magnetic powder, during the process of using magnetic powder-winding molding, the magnetic powder is evenly distributed around the windings in the mold cavity; after pressing, the magnetic core 100 with the windings therein is formed, a suitable distance between the windings in the magnetic core is obtained for insulation by insulating magnetic powder, the magnetic core 100 and the windings are in full contact for rapid heat transfer. The method of magnetic powder-winding molding makes there nearly no gaps inside the inductor, obtaining full space utilization and high power density. The insulating magnetic powder can form a thin insulating layer between contact surfaces of the windings, so that a distance between the windings is enough close and insulated from each other to improve magnetic coupling between the corresponding windings. In other embodiments, the winding 1, 2, 3 and 4 of the multiple windings 10 have been covered with an insulating film on their surface, after being placed in the mold cavity; then perform the process of magnetic powder-winding molding to produce the inductor 1000, and the distance between the windings can also be enough close and insulated from each other to improve magnetic coupling between the corresponding windings. Producing the inductor by the method of magnetic powder-winding molding, the magnetic core and windings are fully contacted for rapid heat transfer, and there is nearly no gap inside the magnetic core, which make full use of space and obtain high power density.

In other embodiments, the magnetic core 100 may be assembled by small magnetic cores each with a cavity inside. The multiple windings 10 is accommodated in the cavity of the magnetic core, and the leads are exposed on the surface of the magnetic core.

In the following embodiments, in order to facilitate showing the structure and arrangement of the windings inside the magnetic core 100, the magnetic core 100 shown in the figures has a “cavity” for placing the windings therein. Substantially, the magnetic core 100 is not transparent and the cavity is not set, while the windings 1, 2, 3 and 4 are fixed (embedded) in the magnetic core 100 by the magnetic powder. The magnetic core 100 shown in the figures is square as a whole, but is not limited to a square shape. An inner bottom wall 110, side walls 120 (including inner side walls 121/122), and top surface 130 of the magnetic core 100 are shown in the figures and described in the following embodiments only for ease illustration of the relative arrangement of the windings within the magnetic core, but not limit the actual shapes or structures or their actual positions. The magnetic core and its internal “cavity” are not limited to be square.

In some exemplar embodiment, the cavity in the magnetic core may be empty and not filled with magnetic powder, the windings are inserted in the magnetic core. The magnetic core 100 may be assembled by multiple (for example, two halves) small magnetic cores, and each of the small magnetic cores has a cavity therein for fixing the windings.

Referring to FIGS. 1-3 and FIG. 8(a), in accordance with a first embodiment of the present invention, the multiple windings 10 in an inner cavity of the magnetic core 100 to form a two-phase coupled inductor 1000. The multiple windings 10 includes two magnetic couplings or two-phase coupling windings, that is a first winding 1, a second winding 2, a third winding 3 and a fourth winding 4. For illustration, the cavity inside the magnetic core can be regards as being defined by the inner bottom wall 110 and the surrounding side walls 120. The multiple windings 10 is accommodated in the cavity, and the cavity is filled with magnetic powder (made by a method of magnetic powder-winding molding). The magnetic powder is evenly distributed between the windings and fixes each winding; or, if the cavity is not filled with magnetic powder, the windings can be fixed by slots in the side wall of the cavity. The leads of the windings are exposed on the surface of the magnetic core 100 such as the top surface 130 for electrical connection with the power supply circuit on the circuit board 200. The first winding 1 and the fourth winding 4 of the multiple windings 10 serve as secondary windings, and each has a pair of leads 11/12 and 41/42 exposed on the surface of the magnetic core 100 to connect with different power stages of the power supply circuit on the circuit board 200. The second winding 2 and the third winding 3, as primary windings, have been internally connected in series inside the magnetic core to form an integrated series winding by an exemplar way that the second winding 2 and the third winding 3 have their adjacent leads merged to form the intermediate conductor 23. The leads 21 or 31 of the second winding 2 and the third winding 3 extend to be exposed on the surface of the magnetic core 100 for electrical connection with the ground points of the power supply circuit. Or, the second winding 2 and the third winding 3 have been connected into an integrated series winding inside the magnetic core by other way that the main bodies of the second winding 2 and the third winding 3 are connected through an intermediate conductor 23, each of the second winding 2 and the third winding 3 only has one lead far apart from each other, and the leads are exposed on the surface of the magnetic core 100 to be connected to the ground points of the power supply circuit.

The first winding 1 and the fourth winding 4 are respectively arranged on both sides of the integrated series winding formed by the second winding 2 and third winding 3 connected in series inside the magnetic core. The first winding 1 and the fourth winding 4 are arranged symmetrically, parallel and aligned to each other. The first winding 1 and the fourth winding 4 are U-shaped, and a pair of leads 11/12 and 41/42 are formed at opposite ends of each winding. The leads are exposed on the surface of the magnetic core to connect with the power supply circuit of the circuit board 200. For example, main bodies of the first winding 1 and the fourth winding 4 are laid flat on the bottom wall 110 inside the magnetic core 100, that is, the windings 1 and 4 are placed in the same first plane. A pair of leads 11/12 of the first winding 1 are respectively bent upward from the bottom wall 110 of the inner cavity of the magnetic core, extend along the opposite side walls 121/122 to the top surface 130 of the magnetic core, and are exposed on the top surface 130 for welding and electrical connection with a pair of weld points A1/A2 of the power supply circuit on the circuit board 200 in FIG. 8(a); a pair of leads 41/42 of the fourth winding 4 are respectively bent upward from the bottom wall 110 of the inner cavity of the magnetic core along the opposite side walls 121/122, extend to the top surface 130 and are exposed on the top surface 130 for welding and electrical connection with a pair of weld points B1/B2 of the power supply circuit on the circuit board 200 in FIG. 8(a). The lead 11 of the first winding 1 and the lead 41 of the fourth winding 4 are arranged in parallel on the side wall 121 of the inner cavity of the magnetic core, that is, the leads 11 and 41 are placed in the same plane. The lead 12 of the first winding 1 and the lead 42 of the fourth winding 4 are arranged in parallel on the side wall 122 (opposite to the side wall 121), that is, the leads 12 and 42 are placed in the same plane. Two pairs of leads of the first winding 1 and the fourth winding 4 are exposed on the same top surface 130 of the magnetic core to form two pairs of electrodes, which are respectively welded to two pairs of weld points of the power supply circuit on the circuit board.

The second winding 2 and the third winding 3 are U-shaped and placed side by side, and have been connected in series to form an integrated series winding inside the magnetic core 100 in the above-mentioned first way or fourth way. Considering two adjacent leads of the second winding 2 and the third winding 3 being merged to form an intermediate conductor 23 to connect the winding 2 and the winding 3 in series, other far apart leads 21 and 31 are vertically bent from the main bodies of the two windings 2 and 3 respectively, and extend to be exposed on the surface of the magnetic core to connect with the circuit board. Or, considering the second winding 2 and the third winding 3 having their main bodies connected in series through an intermediate conductor 23, other far apart leads 21 and 31 are vertically bent from the main bodies of the two windings 2 and 3 respectively, and extend to be exposed on the surface of the magnetic core for electrical connection with the circuit board. For example, the body part of the integrated series winding formed by interconnecting the second winding 2 and the third winding 3 in series inside the magnetic core has a U shape or a Z shape. Specifically, each of the U-shaped second winding 2 and third winding 3 includes a straight main body and one lead at their unconnected (free) end, their main bodies are parallel to each other and their two unconnected leads are parallel to each other; the lead is bent (for example, vertically) from the corresponding main body to extend to be exposed on the surface of the magnetic core. The second winding 2 and the third winding 3 have their two adjacent leads merged by means of machining to form a straight intermediate conductor 23 for connection between their main bodies, thus an integrated series winding is formed. The intermediate conductor 23 vertically connected to the two parallel straight main bodies to form a U-shaped body part of the integrated series winding, and the U-shaped body part is planar (is placed on the same first plane or on the bottom wall 110). Set an xyz three-dimensional coordinate system, the main bodies of the second winding 2 and the third winding 3 can be placed in the xy plane; their two unconnected leads (far leads) 21 and 31 extend in the z-axis direction and respectively from opposite ends of the U-shaped body part of the integrated series winding, and are perpendicular to the U-shaped body part. The intermediate conductor 23 formed by the interconnected leads (two adjacent leads) is located in the xy coordinate plane too, and is connected between the two parallel main bodies of the second winding 2 and the third winding 3.

Preferably, the second winding 2 and the third winding 3 have the same shape and are arranged symmetrically in parallel. The second winding 2 and the third winding 3 are connected to form the body part of the integrated series winding, and are placed flat on the bottom wall 110 inside the magnetic core 100. The leads 21 and 31 are respectively bent upward (for example, vertically bent) from the bottom wall 110 along the side wall 121 of the inner cavity of the magnetic core 100, extend toward the top surface 130, and are exposed on the top surface 130 of the magnetic core for being welded with a pair of weld points (ground points) E2/F2 of the power supply circuit on the circuit board 200 in FIG. 8(a). The two leads 21 and 31 are parallel to each other, and are arranged at intervals and parallel to the corresponding leads 11 and 41 of the first winding 1 and the fourth winding 4. The second winding 2 and the third winding 3 are located between the first winding 1 and the fourth winding 4. For example, the main bodies of the four windings 1, 2, 3 and 4 have the same length and height, and are parallel to each other and aligned at both ends.

The main body and its leads of each winding 1, 2, 3 or 4 in the first embodiment have the same cross-sectional shape such as square, circular or elliptical, or other polygonal or other shapes. The main bodies of the first winding 1, the second winding 2, the third winding 3 and the fourth winding 4 are arranged in parallel on the inner planar bottom wall 110 (the same first plane) of the magnetic core 100. The first winding 1 and the fourth winding 4 are respectively located outside of the second winding 2 and the third winding 3 respectively.

Referring to FIGS. 4-5 and 8(a), the difference between the inductor 1000 of a second embodiment and the first embodiment (FIGS. 1-3 and FIG. 8(a)) is mainly that: the lead cross-sectional dimensions or lead widths of the first winding 1 and the fourth winding 4 are smaller than that of their main bodies; thereby, steps are formed at the connection between the leads and opposite ends of the main body respectively, and the outer edges of the leads and the main body of the corresponding winding are aligned with each other; or, the step may also be formed at any position of the lead so that the cross-sectional dimensions or widths of the leads exposed on the top surface 130 of the magnetic core 100 become narrower and a distance between the leads is increased. The leads 11/12, 41/42 of the first winding 1 and the fourth winding 4 may be integrally formed with the main body or may be formed by machining. Alternatively, the leads can be provided separately and then vertically welded or supported on the corresponding main body; and then the windings are fixed by magnetic powder by the process of magnetic powder-winding molding. When the first winding 1 and the second winding 2 are placed side by side, the step set at the first winding 1 can increase a distance between corresponding adjacent leads 11 and 21 of the first and second windings 1 and 2 exposed on the surface of the magnetic core, which is advantageous for the leads 11 and 21 to be welded and connected to the circuit board 200 and prevent short circuit. When the third winding 3 and the fourth winding 4 are placed side by side, the step set at the fourth winding 4 can increase a distance between the adjacent leads 31 and 41 of the third and fourth windings 3 and 4 exposed on the surface of the magnetic core to facilitate the leads 31 and 41 to be welded and connected to the circuit board 200 to prevent short circuit. In this embodiment, by reducing a width of the leads, a distance between two adjacent leads exposed on the surface of the magnetic core is increased, which facilitates welding the leads to the circuit board and prevents short circuits. By reducing the width of one or two of the adjacent leads of the first winding, the second winding, the third winding, and the fourth winding, especially by reducing the widths of the leads exposed on the surface of the magnetic core, increase a distance between adjacent leads exposed on the surface of the magnetic core so as to prevent short circuits when the leads are welded to the circuit board.

Referring to FIGS. 6-7 and 8(b), the difference between the inductor 1000 of a third embodiment and the first embodiment (FIGS. 1-3 and FIG. 8(a)) is that the second winding 2 and third winding 3 can be regarded as Z-shaped. Each of the Z-shaped second winding 2 and the third winding 3 includes a straight main body and a pair of leads at its opposite ends. The pair of leads are bent relative to the corresponding main body in different space directions, thereby forming Z shape. The two far apart leads of the first and second windings 2 and 3 are bent vertically relative to a plane of the corresponding main body, and the two adjacent leads of the first and second windings 2 and 3 are combined to form an intermediate conductor 23 through mechanical processing to connect the two main bodies of the two windings 2 and 3 end to end so that the second winding 2 and the third winding 3 are connected in series to form an integrated series winding in the magnetic core. The intermediate conductor 23 is coplanar with the main bodies of the two windings 2 and 3 to forming a Z-shaped body part of the integrated series winding, that is, the Z-shaped body part of the integrated series winding is plane, and is placed on the same first plane (bottom wall 110). The far apart leads 22 and 31 of the second and third windings 2 and 3, are not connected to each other, remain original shapes, are bent vertically relative to the (plane of) main bodies respectively in the same direction, and are arranged at opposite ends of the Z-shaped integrated series winding. The body part of the Z-shaped integrated series winding is formed by connecting main bodies of the second winding 2 and the third winding 3 through the intermediate conductor 23 and is laid flat on the bottom wall 110 inside the magnetic core 100. The far apart leads 22 and 31 of the windings 2 and 3 extend to be exposed on the surface of the magnetic core for electrical connection with the ground points of the power supply circuit on the circuit board 200. The second winding 2 and the third winding 3 are connected inside the magnetic core to form an integrated series winding with a centrally symmetrical structure. The second winding 2 and the third winding 3 have the same shape, are Z-shaped windings, and their straight main bodies are placed side by side in parallel. The second winding 2 and the third winding 3 are internally connected to each other form the integrated series winding which have centrally symmetrical leads 22 and 31; the centrally symmetrical leads 22 and 31 are bent upward (or vertically) from the bottom wall 110, extend along the opposite inner walls 121/122 of the inner cavity in the magnetic core to be exposed on the top surface 130 and are parallel to the corresponding leads of the first winding 1 and the fourth winding 4 respectively. The centrally symmetrical leads 22 and 31 of the integrated series winding are exposed on the top surface 130 of the magnetic core 100 for being welded to a pair of weld points E1/F2 as the ground points of the power supply circuit on the circuit board. The second winding 2 and the third winding 3 are located between the first winding 1 and the fourth winding 4. For example, the main bodies of the four windings 1, 2, 3 and 4 have the same length and height, are parallel to each other and are aligned side by side.

In the inductor 1000 of the above embodiments, the multiple windings 10 provided in the magnetic core 100 includes four windings 1, 2, 3 and 4. The second winding 2 and the third winding 3 have been connected in series inside the magnetic core to form an integrated series winding by means of their two adjacent leads being combined or connected to each other, and their far apart leads extends from their main bodies to be exposed on the surface of the magnetic core. A pair of leads of each of the first winding 1 and the fourth winding 4 extend from their main bodies to be exposed on the surface of the magnetic core. A pair of leads of the first winding 1, only one lead of the second winding 2, only one lead of the third winding 3, and a pair of leads of the fourth winding 4 of the multiple windings 10 provided in the magnetic core 100 extend to be exposed on the surface of the magnetic core for being welded and electrically connected to corresponding six weld points of the power supply circuit on the circuit board 200. Only six not eight weld points are set in the power supply circuit on the circuit board 200 to connect one inductor 1000, which saves the number of weld points on the circuit board 200. Further, the second winding 2 and the third winding 3 have been connected in series inside the magnetic core, there is no need to lay out the corresponding series circuit on the circuit board 200, therefore, the electrical connection between the inductor 1000 and the circuit board 200 is more reliable and the DCR is smaller.

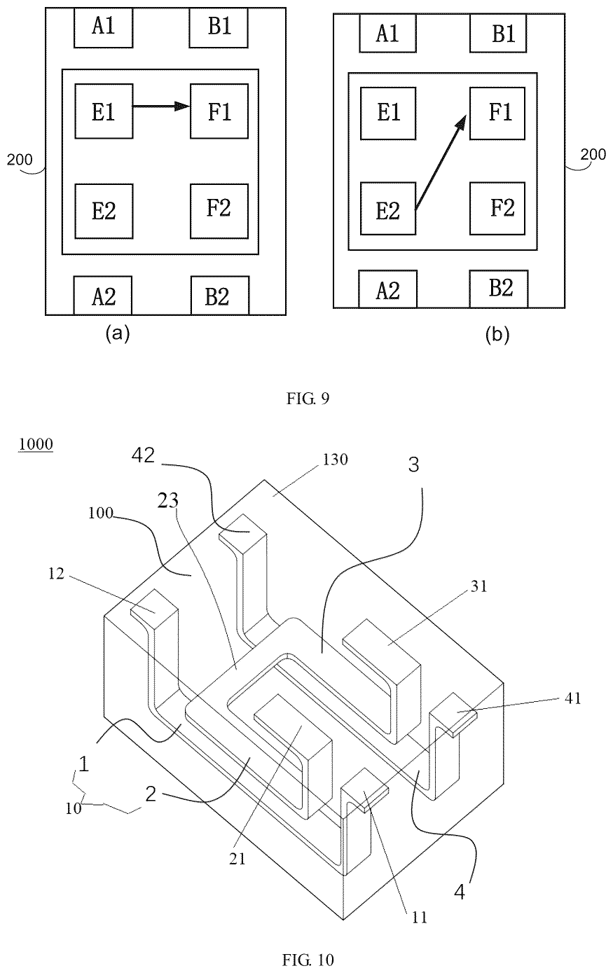

Referring to FIGS. 8 and 9 together, where FIG. 9 (a) is compared with FIG. 8(a), and FIG. 9(b) is compared with FIG. 8(b). If the second winding 2 and the third winding 3 in the above embodiments are not be internally connected in the magnetic core, the multiple windings 10 (including the first winding 1, the second winding 2, the third winding 3 and the fourth winding 4) will have four pairs of leads exposed on the surface of the magnetic core, eight weld points and a series circuit wiring between the weld points E1 and F1 will be set in the power supply circuit on the circuit board (FIG. 9(a)), or, eight weld points and a series circuit wiring between the weld points E2 and F1 will be set in the power supply circuit on the circuit board (FIG. 9(b)). In this invention, the second winding 2 and the third winding 3 have been connected in series in the magnetic core 100, there is no need to set the weld points E1/F1 or E2/F1 as shown in FIG. 9 in the power supply circuit on the circuit board 200, and there is no need to set the series circuit wiring to connect the weld points E1 and F1 or the series circuit wiring to connect the weld points E2 and F1 as shown in FIG. 9, thus the DCR is reduced. Moreover, the second winding 2 and the third winding 3 of the multiple windings 10 are connected in series through the intermediate conductor 23 inside the magnetic core, only have two leads exposed on the surface of the magnetic core for being welded to the ground points in the power supply circuit on the circuit board 200, and the number of weld points in the power supply circuit on the circuit board is two instead of four, thus reducing the chance of circuit disconnection at the weld points and improving circuit reliability.

Referring to FIGS. 10-11, the two-phase coupled inductor 1000 in a fourth embodiment of the present invention includes a magnetic core 100 and multiple windings 10 provided in the magnetic core 100. The multiple windings 10 includes a first winding 1, a second winding 2, a third winding 3 and the fourth winding 4. The inductor 1000 can be produced by a method of magnetic powder-winding molding, the windings are fixed by magnetic powder pressed into an integrated structure. The leads of the winding extend to be exposed on the surface such as the top surface 130 of the magnetic core 100 for being connected to the power supply circuit on the circuit board. The first winding 1 and the fourth winding 4 serve as secondary windings and are connected to different power stages of the power supply circuit. The second winding 2 and the third winding 3 serve as primary windings and are connected to the ground points of the power supply circuit. The first winding 1 and the fourth winding 4 are arranged symmetrically; a pair of leads 11/12 of the first winding 1 and a pair of leads 41/42 of the fourth winding 4 are exposed on the top surface 130 of the magnetic core for electrical connection with the different power stages on the circuit board 200. The second winding 2 and the third winding 3 have been connected inside the magnetic core through the intermediate conductor 23 to form an integrated series winding, that is, two adjacent leads of the second winding 2 and the third winding 3 are merged into the intermediate conductor 23, and the other leads 21 and 31 of the second and third windings 2 and 3 are exposed on the surface of the magnetic core for electrical connection with the ground points of the power supply circuit. The first winding 1 and the fourth winding 4 are respectively located above or below the second winding 2 and the third winding 3. In the inductor 1000 illustrated in FIGS. 10-11, the first winding 1 is located below the second winding 2 and is parallel to each other, and the fourth winding 4 is located below the third winding 3 and is parallel to each other. The first winding 1 and the fourth winding 4 are U-shaped. A pair of leads 11/12 and a pair of leads 41/42 are bent (for example but not limited to, vertically bent) relative to (the plane of) their main bodies of the first and fourth windings 1 and 4 respectively, ends of the leads 11/12 and 41/42 are exposed on the top surface 130 of the magnetic core; then the ends of the leads 11/12 and 41/42 are bent again (for example but not limited to, vertically bent) along the top surface 130, the ends of the leads 11 and 12 extend towards opposite edges of the top surface 130, the ends of the leads 41 and 42 extend towards opposite edges of the top surface 130; the leads 11 and 41 are arranged parallel and spaced apart, and the leads 12 and 42 are arranged parallel and spaced apart. The second winding 2 and the third winding 3 are also U-shaped (refer to the first embodiment). Inside the magnetic core 100, one lead of the second winding 2 is connected to one lead of the third winding 3 to form an integrated series winding. The other leads 21 and 31 are vertically bent relative to the main bodies of the second and third windings 2 and 3 respectively, and are exposed on the top surface 130 of the magnetic core 100. The second winding 2 and the third winding 3 are internally connected to form an integrated series winding, and the body part of the integrated series winding is also U-shaped. One lead 21 of the second winding 2 and one lead 31 of the third winding 3 are provided at opposite ends of the integrated series winding, are bent (for example but not limited to, vertically bent) relative to the plane of the U-shaped body part of the integrated series winding, extend to the top surface 130 of the magnetic core, and are bent again along the top surface 130 (for example but not limited to, vertically bent); therefore, the area exposed on the surface of the magnetic core is increased, the distance between the leads of the first winding 1 and the second winding 2 is increased, and the distance between the fourth winding 4 and the third winding 3 is increased, which facilitates welding the leads with the corresponding weld points of the power supply circuit on the circuit board 200. In this embodiment, the leads 11/12 of the first winding 1 and the leads 41/42 of the fourth winding 4 are bent and extend toward the outer edges of the top surface 130 of the magnetic core 100, and the leads 21 of the second winding 2 and the leads 31 of the third winding 3 are bent and extend on the top surface 130 toward the center of the top surface, therefore, the distance between the leads exposed on the surface of the magnetic core is increased. The first windings 1 and fourth winding 4 are placed parallel and side by side, their main bodies are placed on the same first plane and aligned at both ends, their leads are located at opposite planes, parallel and aligned. Preferably, the first winding 1 and fourth winding 4 are the same winding and are arranged symmetrically left and right side by side. The second and third windings 2 and 3 are placed parallel and side by side, their main bodies are placed on the same second plane and aligned at both ends, that is, the body part of the integrated series winding is planar and is placed on the second plane; their two leads are located at opposite planes, parallel and aligned. Preferably, the first winding 2 and third winding 3 are the same winding and are arranged symmetrically. Ends of the leads of the windings 1, 2, 3 and 4 are exposed on the same (but not limited to the same) surface of the magnetic core. In other embodiments, the inductor 1000 be assembled by multiple magnetic cores with the windings fixed in a cavity of the assembled magnetic cores, and the windings can be fixed in slots set in the inner walls of the cavity in the magnetic cores.

Referring to FIG. 12, the inductor 1000 of the fifth embodiment of the present invention includes a magnetic core 100 with multiple windings 10 therein. The multiple windings 10 include a first winding 1, a second winding 2, and a third winding 3, and fourth winding 4. Parts of the leads of the windings are exposed on the surface (such as the top surface 130) of the magnetic core 100 for electrical connection with the power supply circuit on the circuit board. The first winding 1 and the fourth winding 4 serve as the secondary windings and are connected to different power stages of the power supply circuit. The second winding 2 and the third winding 3 serve as primary windings and are connected to the ground points of the power supply circuit. The first winding 1 and the fourth winding 4 are arranged symmetrically; a pair of leads 11/12 of the first winding 1 and a pair of leads 41/42 of the fourth winding 4 are exposed on the top surface 130 of the magnetic core for electrical connection with different power stages of the power supply circuit of the circuit board 200. The second winding 2 and the third winding 3 have been connected into an integrated series winding inside the magnetic core. The second winding 2 and the third winding 3 have their main bodies connected to form a straight body part of the integrated series winding with their two leads 21 and 32 at opposite ends of the straight body part exposed on the surface of the magnetic core for connection with the ground points of the power supply circuit. The first winding 1 and the fourth winding 4 are respectively located above the second winding 2 and the third winding 3, that is, the first winding 1 and fourth winding 4 are located in the integrated series winding. In the inductor 1000 illustrated in FIG. 12, the second winding 2 and the third winding 3 are internally connected in series to form a U-shaped integrated series winding with a straight body part and two leads 21 and 32 bent at the ends of the straight body. The two leads 21 and 32 as the arms of the U-shape, are bent from the straight body part and extend to the top surface 130 of the magnetic core, are bent again along the top surface 130 and extend toward opposite edges of the top surface 130, therefore, the area of the leads exposed on the surface of the magnetic core is increased, and the distance between the leads of the first winding 1 and the fourth winding 4 exposed on the surface of the magnetic core is increased, which facilitates welding the leads to the corresponding weld points of the power supply circuit on the circuit board 200. The first winding 1 and the fourth winding 4 are accommodated inside the integrated U-shaped series winding formed by the connection of the second winding 2 and the third winding 3 in series. Correspondingly, the first winding 1 is located above the second winding 2, and the fourth winding 4 is located above the third winding 3. The first winding 1 and the fourth winding 4 are placed along a length direction of the body part of the integrated series winding, and are correspondingly parallel to each other. The first winding 1 and the fourth winding 4 are U-shaped. A pair of leads 11/12 of the first winding 1 and a pair of leads 41/42 of the fourth winding 4 are vertically bent relative to their straight main body, are exposed on the top surface 130 of the magnetic core; and then the leads 11/12 and 41/42 are respectively folded and extended inwards again along the top surface 130. In this embodiment, the leads 11/12 of the first winding 1 and the leads 41/42 of the fourth winding 4 are folded and extend on the top surface 130 of the magnetic core 100, and the leads 21 of the second winding 2 are the lead 32 of the winding 3 are bent and extended outward on the top surface 130 to increase the distance between the leads exposed on the surface of the magnetic core. The four windings 1, 2, 3, 4 are placed along the same straight line and located in the same vertical plane, the straight body part of the integrated series winding is located in the same first horizontal plane, and main bodies of the first and fourth windings 1 and 4 are located in the same second horizontal plane.

Referring to FIG. 13, the inductor 1000 of the sixth embodiment of the present invention includes a magnetic core 100 and multiple windings (two phase coupling windings) 10 provided in the magnetic core 100. The multiple windings 10 includes a first winding 1, a second winding 2, and a third winding 3, and a fourth winding 4. The leads of the winding are exposed on the surface of the magnetic core 100 for electrical connection with the power supply circuit on the circuit board. The first winding 1 and the fourth winding 4 in the multiple windings 10 serve as secondary windings and are connected to different power stages of the power supply circuit. The second winding 2 and the third winding 3 serve as primary windings and are connected to the ground points of the power supply circuit. The first winding 1 and the fourth winding 4 are arranged symmetrically; a pair of leads 11/12 of the first winding 1 and a pair of leads 41/42 of the fourth winding 4 are exposed on the top surface 130 of the magnetic core to be connected with different power stages on the circuit board 200. The second winding 2 and the third winding 3 are connected to form an integrated series winding inside the magnetic core by means that the adjacent leads of the second winding 2 and the third winding 3 are merged or the two main bodies are directly connected. The far apart leads 21 and 32 of the first winding 2 and the third winding 3 are exposed on the surface of the magnetic core to be connected to the ground points of the power supply circuit. The first winding 1 and the second winding 2 are coupled to each other and are arranged in parallel to each other side by side; and the fourth winding 4 and the third winding 3 are coupled to each other and are arranged in parallel to each other side by side. In the two-phase coupled inductor 1000 illustrated in FIG. 13, the first winding 1 is located at one side of the second winding 2, the fourth winding 4 is located at the same side of the third winding 3 and parallel to each other, the main bodies of the four windings 1-4 are located in the same first horizontal plane, that is the main bodies are planar. The first winding 1 and the fourth winding 4 are U-shaped. A pair of leads 11/12 of the first winding 1 and a pair of leads 41/42 of the fourth winding 4 are vertically bent relative to the corresponding straight main bodies of the winding 1 and 4 respectively. The leads 11 and 12 are exposed on the top surface 130 of the magnetic core and are vertically folded and extend inwards again along the top surface 130; and the leads 41 and 42 are exposed on the top surface 130 of the magnetic core and are vertically folded and extend inwards again along the top surface 130. The second winding 2 and the third winding 3 are also U-shaped windings. Each of the second winding 2 and the third winding 3 has one end merged, or the main bodies of the windings 2 and 3 are directly connected, so that the windings 2 and 3 form an integrated series winding in a U-shape. The other leads 21, 32 vertically bent relative to the main bodies of the two winding 2 and 3 and exposed on the top surface 130 of the magnetic core 100. The straight body part of the integrated series winding is parallel to the main bodies of the winding 1 and 4 placed end to end at an interval, and the ends of the straight body part is aligned to a front end of the winding 1 and the rear end of the winding 4. Front leads 21 and 11 are parallel and aligned to each other on a front plane, rear leads 32 and 42 are parallel and aligned to each other on a rear plane. Ends of the leads 11, 12, 41 and 42 are exposed on the same surface 130 of the magnetic core and arranged along the same lines.

Referring to FIG. 14, the two-phase coupled inductor 1000 of the seventh embodiment of the present invention includes a magnetic core 100 and multiple windings (two-phase coupling windings) 10 provided in the magnetic core 100. The multiple windings 10 includes a first winding 1, a second winding 2, and a third winding 3, and fourth winding 4. The leads of the winding are exposed on the surface (for example, on the top surface 130) of the magnetic core 100 for connection with the power supply circuit on the circuit board. The first winding 1 and the fourth winding 4 serve as the secondary windings and are connected to different power stages in the power supply circuit. The second winding 2 and the third winding 3 serve as primary windings and are connected to the ground points of the power supply circuit. The first winding 1 and the fourth winding 4 are arranged symmetrically, end to end at an interval therebetween; the leads of a pair of leads 11/12 of the first winding 1 and a pair of leads 41/42 of the fourth winding 4 are exposed on the top surface 130 of the magnetic core for electrical connection with different power stages of the power supply circuit on the circuit board 200. Inside the magnetic core, the second winding 2 and the third winding 3 have been connected to form an internal series winding, that is, the adjacent leads of the second winding 2 and the third winding 3 are connected through the intermediate conductor 23, and their far apart leads 21 and 32 are exposed on the surface of the magnetic core for being welded to the ground points of the power supply circuit. The first winding 1 and the second winding 2 are coupled and arranged side by side and parallel to each other, and the fourth winding 4 and the third winding 3 are coupled to and arranged side by side and parallel to each other. In the inductor 1000 illustrated in FIG. 14, the first winding 1 is located on one side of the second winding 2 and parallel to each other, and the fourth winding 4 is located on one side of the third winding 3 and parallel to each other. The first winding 1 and the fourth winding 4 are U-shaped. A pair of leads 11/12 of the first winding 1 and a pair of leads 41/42 of the fourth winding 4 are vertically bent relative to their straight main bodies respectively, are exposed on the top surface 130 of the magnetic core, are vertically folded and extend inwards again along the top surface 130. The second winding 2 and the third winding 3 are also U-shaped. The adjacent leads of the second winding 2 and the third winding 3 are connected through an intermediate conductor 23, the other far leads 21 and 32 are vertically bent, are exposed on the top surface 130 of the magnetic core; and are folded and extended vertically inward again along the top surface 130; therefore, the area of the leads 21 and 32 exposed on the surface of the magnetic core is increased to facilitate welding the inductor with the corresponding weld points of the power supply circuit on the circuit board 200. In this embodiment, the second windings 2 and third windings 3 are U-shaped, have their adjacent vertical leads connected horizontally through an intermediate conductor 23 to form an integrated series winding. The adjacent vertical leads are connected horizontally. The intermediate conductor 23 is straight. The integrated series winding formed by connecting the second winding 2 and the third winding 3 inside the magnetic core includes three U-shapes connected end to end. The opening direction of the middle U-shape is opposite to other two U-shapes on both sides. The middle U-shape is formed by connecting the adjacent leads of the windings 2 and 3 through the intermediate conductor 23, and the U-shapes on both sides are the second winding 2 and the third winding 3, which are aligned in parallel with the U-shaped first winding 1 and the fourth winding 4 respectively. The middle U shape corresponds to an interval between the first winding 1 and the fourth winding 4. The straight main bodies of the four windings 1, 2, 3 and 4 are placed on the same first plane, that is, the straight main bodies are planar, the first and four winding 1 and 4 are placed end to end at an interval, the integrated series winding has its ends of the straight body part is aligned to a front end of the winding 1 and the rear end of the winding 4. Front leads 21 and 11 are parallel and aligned to each other on a front plane, rear leads 32 and 42 are parallel and aligned to each other on a rear plane. Ends of the leads are exposed on the same surface 130 of the magnetic core and arranged along two parallel lines.

When the inductor 1000 is connected to the circuit board 200, in the energized state, the first winding 1 and the winding 2 are magnetically coupled, and the third winding 3 and the fourth winding 4 are magnetically coupled.

It should be noted that the shape, cross-section, size and position arrangement of the windings of the first winding 1, the second winding 2, the third winding 3 and the fourth winding 4 can be adjusted according to the application scenario. There is a certain projection overlap between the first winding 1 and the second winding 2, and there is a certain projection overlap between the third winding 3 and the fourth winding 4. The leads of the windings exposed on the surface of the magnetic core can be bent and extend in various ways according to the layout of the weld points on the circuit board.

In the present invention, the second winding 2 and the third winding 3 have been internally connected to form an integrated series winding inside the magnetic core 10. The shape of the integrated series winding is various, such as single or multiple U-shapes or Z-shapes as described in the above various embodiments. Inside the magnetic core 100, based on the integrated series winding by connecting one second windings 2 and one third winding 3, add one more second winding 2 or one more third winding 3, and one more first winding 1 or one more fourth winding 4 is added correspondingly in the magnetic core, thereby multiphase coupled and integrated inductor can be obtained. The second winding 2 or third winding 3 have their adjacent leads connected by an intermediate conductor or are directly merged to form an intermediate conductor or are cut while have their main bodies directly connected end to end, so as to form an integrated series winding inside the magnetic core 100. The other two far apart (unconnected) leads of the windings 2 and 3 extend to be exposed on the surface of the magnetic core 100 for electrical connection with two ground points of the power supply circuit on the circuit board. The two adjacent leads of windings 2 and 3 are interconnected and are not welded to the circuit board. Each second winding 2 is magnetically coupled to one first winding 1, and each third winding 3 is magnetically coupled to one fourth winding 4. Preferably, the first winding 1 and the fourth winding 4 are the same and are U-shaped; and the second winding 2 and the third winding 3 are U-shaped or Z-shaped.

When the inductor 1000 has three windings, four windings or even more windings integrated into the magnetic core 100, the series circuit wiring and the weld points of the power supply circuit on the circuit board 200 for welding the inductor can be reduced. When the windings are arranged up and down, for example, the second winding 2 is arranged above the first winding 1, the third winding 3 is arranged above the fourth winding 4, and the space occupied by the inductor on the circuit board 200 is reduced to a greater extent. Moreover, when the coupled windings are arranged up and down, compared with the coupled windings being arranged left and right (side by side), more or all the secondary windings of the multiple windings can be electrically connected in series in the magnetic core so that the number of leads exposed on the surface of the magnetic core is reduced, reducing the series circuit wiring and the weld points on the circuit board 200, reducing DCR to a greater extent, and improving the electrical connection reliability between the inductor and the circuit board 200.

The inductor 1000 of the above embodiments of the present invention is applied to power supplies with high power and high operating currents, including but not limited to power supplies for servers, data centers, power processors of storage systems, and memories, etc. The power supply includes one or more inductors 1000 and the circuit board 200. The circuit board 200 is provided with a power supply circuit. One or more inductors 1000 are connected to the power supply circuit on the circuit board 200. The power supply using the inductor 1000 of this invention has the following advantages:
1) in the inductor of the present invention, one or more second and third windings are connected in series inside the magnetic core for electrically connection with the ground points of the power supply circuit on the circuit board, when the inductor is connected to the circuit board, only two leads at the first and last ends of the one or more second and third windings connected in series are welded to the two weld points on the circuit board, there is no need to provide corresponding two weld points on the circuit board for each pair of leads of each second winding and each third winding, therefore, the number of weld points on the circuit board 200 is reduced, the electrical connection reliability is higher and the DCR is smaller;
2) in the inductor of the present invention, one or more second and third windings have been connected in series inside the magnetic core, there is no need to lay out corresponding series circuit wiring on the circuit board, and there are fewer circuit layout lines, so there is sufficient volume to lay out chips (such as CPU and GPU) to increase the computing power of the chips;
3) the inductor of the present invention can be integrated with multiple magnetic couplings or multiphase and is smaller in size.

The technical features of the above embodiments can be combined arbitrarily. In order to make the description simple, all possible combinations of the technical features in the above embodiments are not described. However, as long as there is no contradiction in the combination of these technical features It is considered to be the range described in this specification.

The above examples only represent several embodiments of the present invention, and the descriptions thereof are specific and detailed, but should not be construed as a limitation on the scope of the invention patent. It should be pointed out that for those of ordinary skill in the art, without departing from the concept of the present invention, several modifications and improvements can also be made, which all belong to the protection scope of the present invention. Therefore, the protection scope of the patent of the present invention should be subject to the appended claims.

What is claimed is:

1. An inductor, comprising a magnetic core and multiple windings provided in the magnetic core with leads exposed on a surface of the magnetic core for electrical connection with a power supply circuit on a circuit board; wherein the multiple windings comprises a first winding, a second winding, a third winding and a fourth winding; the second winding and the third winding have been internally connected in series to form an integrated series winding inside the magnetic core; two leads of the integrated series winding extend to be exposed on the surface of the magnetic core; the first winding is magnetically coupled to the second winding, the fourth winding is magnetically coupled to the third winding; a pair of leads at both ends of the first winding and a pair of leads at both ends of the fourth winding extend to be exposed on the surface of the magnetic core.

2. The inductor as claimed in claim 1, wherein the first winding, the second winding, the third winding and the fourth winding are configured that there is a predetermined projection overlap between the first winding and the second winding, and there is a predetermined projection overlap between the third winding and the fourth winding.

3. The inductor as claimed in claim 1, wherein the first winding is located outside, above or below the second winding; the fourth winding is located outside, above or below the third winding.

4. The inductor as claimed in claim 1, wherein the second winding and the third winding are primary windings for electrical connection with ground points of the power supply circuit; the first winding and the fourth winding are secondary windings for electrical connection with different power stages of the power supply circuit.

5. The inductor as claimed in claim 4, wherein the second winding and the third winding have been internally connected in series to form the integrated series winding inside the magnetic core in any of following ways:
a first way that: merging two adjacent leads of the second winding and the third winding to form an intermediate conductor for connecting between the second winding and the third winding to form the integrated series winding with the two leads extending to be exposed on the surface of the magnetic core;
a second way that: connecting two adjacent leads of the second winding and the third winding through an intermediate conductor whereby the second winding and the third winding are connected in series to form the integrated series winding with the two leads extending to be exposed on the surface of the magnetic core;
a third way that: two adjacent leads of the second winding and the third winding are not set, and the second winding and the third winding have their main body directly connected end to end in series to form the integrated series winding with the two leads extending to be exposed on the surface of the magnetic core;
a fourth way that: two adjacent leads of the second winding and the third winding are not set, and the second winding and the third winding have their main body connected in series through an intermediate conductor to form the integrated series winding with the two leads extending to be exposed on the surface of the magnetic core.

6. The inductor as claimed in claim 5, wherein the first winding and the fourth winding are U-shaped; the second winding and the third winding are U-shaped or Z-shaped; the integrated series winding comprises a body part and the two leads; the body part of the integrated series winding forms a single or multiple U-shapes or Z-shapes or a straight line.

7. The inductor as claimed in claim 6, wherein the two leads of the integrated series winding are bent relative to the body part of the integrated series winding, then extend to be exposed on the surface of the magnetic core; and the two leads are arranged at first and last ends of the integrated series winding.

8. The inductor as claimed in claim 1, wherein each of the first winding, the second winding, the third winding, and the fourth winding comprises a main body and one or two leads; the one or two leads are provided at one or both ends of the main body, are bent relative to the main body and extend to be exposed on the surface of the magnetic core.

9. The inductor as claimed in claim 8, wherein the one or two leads of each winding have the same cross-sectional shape as the main body of the corresponding winding; or, a width of one or both of two adjacent leads is reduced to increase a distance between the two adjacent leads exposed on the surface of the magnetic core to prevent short circuits when the leads are welded to the power supply circuit on the circuit board.

10. The inductor as claimed in claim 8, wherein the leads of the first winding, the second winding, the third winding and the fourth winding that are exposed on the surface of the magnetic core are bent again and extend along the surface of the magnetic core to increase a distance between the adjacent leads exposed on the surface of the magnetic core and to expand areas of the leads exposed on the surface of the magnetic core to facilitate welding the leads to the circuit board.

11. The inductor as claimed in claim 1, wherein the first winding, the second winding, the third winding and the fourth winding are arranged side by side along a first direction, the first winding is arranged close to the second winding, and the third winding is arranged close to the fourth winding; or
the first winding and the fourth winding are arranged side by side along a first direction, the second winding and the third winding are arranged along a second direction and correspond to the first winding and the fourth winding respectively.

12. The inductor as claimed in claim 11, wherein the first direction and the second direction are perpendicular to each other; or, the first direction is parallel to the second line.

13. The inductor as claimed in claim 1, wherein the first winding and the second winding are arranged in parallel, the fourth winding and the third winding are arranged in parallel; the first winding and the fourth winding are the same; the second winding and the third winding are the same; and ends of the leads of the first winding, the second winding, the third winding and the fourth winding are exposed on the same side surface of the magnetic core.

14. The inductor as claimed in claim 8, wherein the main bodies of the multiple windings are placed in the same plane.

15. The inductor as claimed in claim 8, wherein the main bodies of the second and third windings are placed in the same plane; the first and fourth windings are placed in a first same plane, the first and second planes are located up and down in parallel.

16. The inductor as claimed in claim 1, wherein the multiple windings comprises one or more first windings, one or more second windings, one or more third windings, and one or more fourth windings, which are set in the magnetic core according to a principle that: add one more second winding and/or one more third winding, then one more first winding and/or one more fourth winding is added correspondingly inside the magnetic core; one second winding and one third winding have been connected in series in the magnetic core to form the integrated series winding, other second and third windings have been connected in series in the magnetic core or not electrically connected in the magnetic core; whereby multiphase coupled inductor is obtain.

17. A power supply, comprising a circuit board, wherein there is a power supply circuit laid out on the circuit board; one or more inductors are welded to the power supply; the inductor comprises a magnetic core and multiple windings provided in the magnetic core with leads exposed on a surface of the magnetic core for electrical connection with a power supply circuit on a circuit board; the multiple windings comprises a first winding, a second winding, a third winding and a fourth winding; the second winding and the third winding have been internally connected in series to form an integrated series winding inside the magnetic core; two leads of the integrated series winding extend to be exposed on the surface of the magnetic core; the first winding is magnetically coupled to the second winding, the fourth winding is magnetically coupled to the third winding; a pair of leads at both ends of the first winding and a pair of leads at both ends of the fourth winding extend to be exposed on the surface of the magnetic core.

18. The power supply as claimed in claim 17, wherein, corresponding to the integrated series winding inside the magnetic core, the power supply circuit provides two ground points for being respectively welded and electrically connected with the two leads at both ends of the integrated series winding; corresponding to each of the first winding and the fourth winding, the power supply circuit provides a pairs of weld points for being respectively welded and electrically connected to the pairs of leads of each of the first winding and the fourth winding.

19. The power supply as claimed in claim 18, wherein the second winding and the third winding are primary windings for electrical connection with ground points of the power supply circuit; the first winding and the fourth winding are secondary windings for electrical connection with different power stages of the power supply circuit.

20. The power supply as claimed in claim 17, wherein the power supply is used as the power supply for a server, or a data center, or a power processor of a storage system, or a memory; an operating current of the power supply reaches an ampere level; and the operating current of the power supply ranges from tens to hundreds of amperes.
